(19) United States
(12) Patent Application Publication
(10) Pub. No.: US 2003/0218202 A1
(43) Pub. Date: Nov. 27, 2003

(54) Semiconductor device and method of manufacturing the same

(75) Inventor: Naoyuki Sato, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: Fujitsu Limited, Kawasaki (JP)

(21) Appl. No.: 10/355,172

(22) Filed: Jan. 31, 2003

(30) Foreign Application Priority Data
May 27, 2002 (JP) 2002-151951

(51) Int. Cl. H01L 27/108

(52) U.S. Cl. 257/306

(57) ABSTRACT

There are provided a first insulating film formed over a semiconductor substrate, an adhesion layer formed on the first insulating film and made of titanium oxide having grains a width of which is larger than a height, a capacitor lower electrode formed on the adhesion layer and containing a noble metal, a capacitor dielectric film formed on the capacitor lower electrode and made of ferroelectric material, and a capacitor upper electrode formed on the capacitor dielectric film.

### CROSS-REFERENCE TO RELATED APPLICATIONS

This application is based upon and claims priority of Japanese Patent Application No. 2002-151951, filed on May 27, 2002, the contents being incorporated herein by reference.

### BACKGROUND OF THE INVENTION

1. Field of the Invention

The present invention relates to a semiconductor device and a method of manufacturing the same and, more particularly, a semiconductor device having a ferroelectric capacitor and a method of manufacturing the same.

2. Description of the Prior Art

As the nonvolatile memory that can still store information after the power supply is turned OFF, the flash memory or the ferroelectric memory (FeRAM) has been known.

The flash memory has the floating gate that is buried in the gate insulating film of the insulated-gate field effect transistor (IGFET), and then stores the information by accumulating the charge, which represents stored information, in the floating gate. The tunnel current that passes through the gate insulating film must be flown to write/erase the information. The relatively high voltage is required.

The FeRAM has the ferroelectric capacitor that stores the information by utilizing the hysteresis characteristic of the ferroelectric substance. The ferroelectric film, which is formed between the upper electrode and the lower electrode in the ferroelectric capacitor, generates the polarization in response to the voltage applied between the upper electrode and the lower electrode, and has the spontaneous polarization that still holds the polarization even after the applied voltage is removed.

If the polarity of the applied voltage is inverted, the polarity of the spontaneous polarization is also inverted. The information can be read by sensing the polarity and magnitude of this spontaneous polarization. The FeRAM can operate at the lower voltage than the flash memory, and thus has such an advantage that the high-speed writing can be attained at a saving of electric power.

As the capacitor used in the FeRAM memory cell, the planar capacitor having the structure in which the wiring contact region is provided to its upper surface is employed.

The planar ferroelectric capacitor is formed by the steps shown in FIGS. 1A and 1B, for example.

First, as shown in FIG. 1A, a metal oxide film 103, a first metal film 104, a ferroelectric film 105, and a second metal film 106 are formed on an interlayer insulating film 102 that covers a silicon substrate 101. Then, as shown in FIG. 1B, a capacitor upper electrode 106a is formed by patterning the second metal film 106, and a capacitor dielectric film 105a is formed by patterning the ferroelectric film 105. In addition, the first metal film 104 is shaped into a capacitor lower electrode 104a by patterning the first metal film 104 and the metal oxide film 103.

Meanwhile, in Patent Application Publication (KOKAI) Hei 10-22463, a titanium oxide film is formed as the metal oxide film 103, and a metal film made of platinum, platinum alloy, iridium, iridium oxide, or the like is formed as the first metal film 104. In this Publication, as the method of forming the titanium oxide film by one step, there are listed the oxygen-introduced electron beam deposition method, the oxygen-introduced RF sputtering method, the oxygen-introduced DC sputtering method, etc. Also, as the method of forming the titanium oxide film by plural steps, there is set forth the method of forming the titanium film by virtue of the DC sputtering method, the RF sputtering method, or the electron beam deposition method and then partially oxidizing the titanium film by annealing a part of the titanium film in the oxygen atmosphere.

By the way, in order to increase the spontaneous polarization of the ferroelectric film 105, e.g., the PZT film, constituting the capacitor dielectric film 105a, a (222) face orientation intensity of the platinum film constituting the capacitor lower electrode 104a must be enhanced. Also, in order to enhance the (222) face orientation intensity of the platinum film, a (200) face orientation intensity of the face orientation of the titanium oxide film must be enhanced.

In order to enhance the (200) face orientation intensity of the titanium oxide film, it is preferable that the titanium film should be formed on the insulating film and then the titanium oxide film should be formed by oxidizing the titanium film in the oxygen atmosphere.

However, if the titanium oxide film is formed by oxidizing the titanium film while introducing the oxygen gas only into the oxidizing atmosphere, surface roughness of the titanium oxide film is generated. Accordingly, it is possible that surface roughness of the platinum film formed on the titanium oxide film is also caused.

Also, if the surface roughness of the platinum film constituting the lower electrode is enhanced, there is a possibility that failure in the connection between the capacitor lower electrode and the leading wiring is caused.

### SUMMARY OF THE INVENTION

It is an object of the present invention to provide a semiconductor device equipped with a capacitor having a lower electrode that is formed on a titanium oxide film whose orientation intensity is improved, and a method of manufacturing the same.

According to one aspect of the present invention, there is provided a semiconductor device comprising: a first insulating film formed over a semiconductor substrate; an adhesion layer formed on the first insulating film and made of titanium oxide having grains a width of which is larger than a height; a capacitor lower electrode formed on the adhesion layer and containing a noble metal; a capacitor dielectric film formed on the capacitor lower electrode and made of ferroelectric material; and a capacitor upper electrode formed on the capacitor dielectric film.

The above subject can be overcome by providing a semiconductor device manufacturing method which comprises the steps of forming a first insulating film over a semiconductor substrate; forming a titanium film on the first insulating film; forming a titanium oxide film by oxidizing the titanium film in an atmosphere into which an oxygen gas is introduced at a flow rate ratio of less than 50%; forming a first conductive film made of a noble metal on the titanium oxide film; forming a ferroelectric film on the first conductive film; forming a second conductive film on the ferroelectric film; forming an upper electrode of a capacitor by patterning the second conductive film; forming a dielectric film of the capacitor by patterning the ferroelectric film; and forming a lower electrode of the capacitor by patterning the first conductive film.

According to the present invention, the adhesion layer made of the titanium oxide having the grains, a width of which is larger than a height, is provided between the lower electrode, which is made of noble metal constituting the capacitor, and the underlying insulating film. The titanium oxide film having such grain size is formed by oxidizing the titanium film while heating it in the atmosphere into which the oxygen gas is introduced at the flow rate ratio of less than 50%, preferably less than 10%.

Therefore, the aspect ratio of the grains of the titanium oxide film becomes smaller than the titanium oxide film that is formed by oxidizing the titanium film at the oxygen flow rate ratio of 100%. Also, the (200) face orientation intensity is enhanced and also the planarization is excellent.

With the improvement of the planarization of the adhesion layer, the planarization of the lower electrode formed on the adhesion layer is improved. Thus, the contact to the wiring connected to the lower electrode is improved. Also, as the (200) face orientation intensity of the adhesion layer is enhanced, the (222) face orientation intensity of the metal film, e.g., the platinum film, used as the lower electrode formed thereover is enhanced. Therefore, since the (222) face orientation intensity of the lower electrode is enhanced, film quality of the ferroelectric film formed on the lower electrode is improved.

In addition, in the case that the capacitor lower electrode is formed of the platinum film, the platinum film is formed at the temperature of less than 100° C. by the sputter method. Therefore, in the state which the aluminum wiring is connected to the capacitor lower electrode via the conductive underlying film, e.g., the titanium nitride film, reaction product made of aluminum and platinum is seldom formed in the contact portion.

### BRIEF DESCRIPTION OF THE DRAWINGS

FIGS. 1A and 1B are sectional views showing steps of forming the capacitor in the prior art;

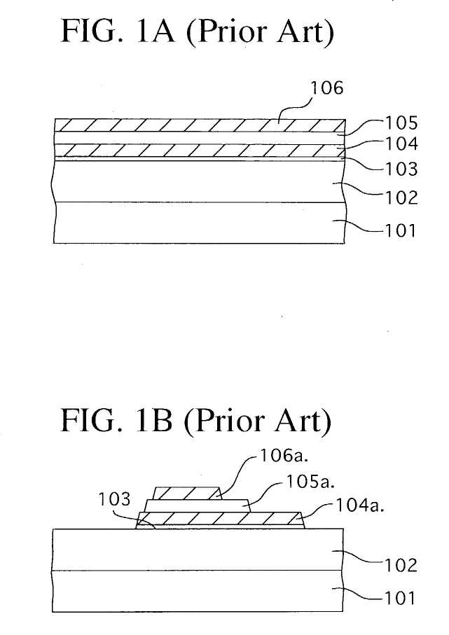

FIGS. 2A to 2J are sectional views showing steps of manufacturing a semiconductor device according to an embodiment of the present invention;

FIG. 3 is a view showing dependency of a (200) face orientation integrated intensity of the XRD pattern and a (200) face orientation half width on forming conditions of a titanium oxide film that constitutes an adhesion layer of a capacitor lower electrode of a semiconductor device according to an embodiment of the present invention;

FIG. 4 is a view showing the titanium oxide film formed by oxidizing a titanium film while setting a flow rate ratio of oxygen to 1%;

FIG. 5 is a view showing the titanium oxide film formed by oxidizing the titanium film while setting the flow rate ratio of oxygen to 100%;

FIG. 6 is a view showing a (222) face orientation integrated intensity of the XRD pattern of a platinum film formed on the titanium oxide film that is formed by oxidizing the titanium film while differentiating the flow rate ratio of oxygen;

FIG. 7 is a graph showing a relationship between a film forming temperature of Pt constituting the capacitor lower electrode and a fraction defective of FeRAM;

FIG. 8 is a plan view showing a monitor capacitor having the same structure as the capacitor of the semiconductor device according to the embodiment of the present invention;

FIGS. 9A and 9B are plan views showing whether or not degradation of a lower electrode contact region is caused due to differences in the forming conditions of the platinum lower electrode constituting the monitor capacitor shown in FIG. 8;

FIG. 10 is a sectional view showing a connected portion between the capacitor lower electrode, which is made of platinum formed at a substrate temperature of 550° C., and an aluminum wiring; and

FIG. 11 is a sectional view showing a connected portion between the capacitor lower electrode, which is made of platinum formed at the substrate temperature of 100° C., and the aluminum wiring.

### DETAILED DESCRIPTION OF THE PREFERRED EMBODIMENT

An embodiment of the present invention will be explained with reference to the drawings hereinafter.

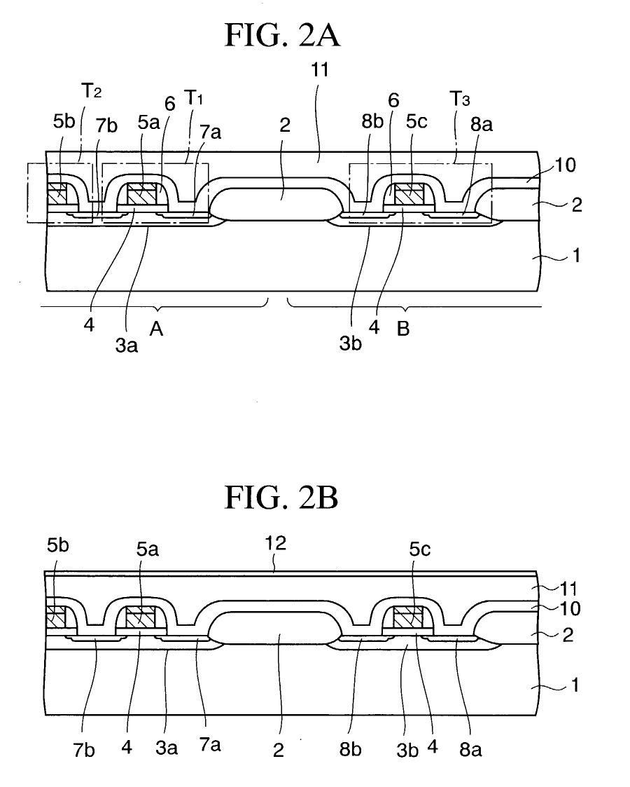

FIGS. 2A to 2J are sectional views showing steps of manufacturing a semiconductor device according to an embodiment of the present invention.

First, steps required until a sectional structure shown in FIG. 2A is formed will be explained hereunder.

In FIG. 2A, an element isolation insulating film 2 is formed on a surface of a p-type silicon (semiconductor) substrate 1 by the LOCOS (Local Oxidation of Silicon) method. In this case, the STI (Shallow Trench Isolation) structure may be employed as the element isolation insulating film 2.

After the element isolation insulating film 2 is formed, the p-type impurity and the n-type impurity are introduced selectively into predetermined active regions (transistor forming regions) in a memory cell region A and a peripheral circuit region B of the silicon substrate 1 respectively. Thus, a p-well 3a is formed in the active region of the memory cell region A, and an n-well 3b is formed in the active region of the peripheral circuit region B.

In this case, in FIGS. 2A to 2J, a part of the p-well 3a is omitted from illustration. Also, the p-well (not shown) is formed in the peripheral circuit region B to form the CMOS.

Then, a silicon oxide film that is used as a gate insulating film 4 on respective surfaces of the p-well 3a and the n-well 3b is formed by thermally oxidizing the surface of the silicon substrate 1.

Then, a polysilicon or amorphous silicon film and a tungsten silicide film are formed sequentially on the element isolation insulating film 2 and the gate insulating film 4. Then, the silicon film and the tungsten silicide film are patterned into a predetermined shape by the photolithography method. Thus, gate electrodes 5a, 5b are formed on the p-well 3a and a gate electrode 5c is formed on the n-well 3b. In this case, a part of one gate electrode 5b on the p-well 3a is omitted from illustration.

In the memory cell region A, two gate electrodes 5a, 5b are formed on the p-well 3a in almost parallel at an interval. These gate electrodes 5a, 5b are extended onto the element isolation insulating film 2 to serve as the word line.

Then, first and second n-type impurity diffusion regions 7a, 7b and a third n-type impurity diffusion region (not shown), which serve as source/drain of n-channel MOS transistors T₁, T₂, are formed by ion-implanting the n-type impurity into the p-well 3a in the memory cell region A on both sides of the gate electrodes 5a, 5b. The second n-type impurity diffusion region 7b positioned in the middle of the p-well 3a is connected electrically to the bit line described later. Also, the first n-type impurity diffusion region 7a and the third n-type impurity diffusion region (not shown) position on both sides of the p-well 3a are connected electrically to the capacitors, described later, respectively.

Then, first and second p-type impurity diffusion region 8a, 8b, which serve as source/drain of a p-channel MOS transistor T₃, are formed by ion-implanting the p-type impurity into the n-well 3b of the peripheral circuit region B on both sides of the gate electrode 5c.

Then, an insulating film is formed on the silicon substrate 1, the element isolation insulating film 2, and the gate electrodes 5a, 5b, 5c. Then, sidewall insulating films 6 are left on both side portions of the gate electrodes 5a to 5c by etching back the insulating film. As the insulating film, silicon oxide (SiO₂) formed by the CVD method, for example, is employed.

Then, the n-type impurity is ion-implanted into the first and second n-type impurity diffusion regions 7a, 7b and the third n-type impurity diffusion region by using the gate electrodes 5a, 5b and the sidewall insulating films 6 on the p-well 3a as a mask. Thus, the n-type impurity diffusion regions are formed into the LDD structure. Also, the p-type impurity is ion-implanted into the first and second p-type impurity diffusion region 8a, 8b, by using the gate electrode 5c and the sidewall insulating films 6 on the n-well 3b as a mask. Thus, the first and second p-type impurity diffusion region 8a, 8b, are formed into the LDD structure.

In this case, individual ion-implantation of the n-type impurity and the p-type impurity is carried out separately by using the resist patterns (not shown).

Accordingly, formation of the first nMOS transistor T₁ having the first and second n-type impurity diffusion regions 7a, 7b and the gate electrode 5a and formation of the second nMOS transistor T₂ having the second n-type impurity diffusion regions 7b and the third n-type impurity diffusion region and the gate electrode 5b are completed. Also, formation of the pMOS transistor T₃ having the first and second p-type impurity diffusion region 8a, 8b, and the gate electrode 5c is completed.

Then, a cover film 10 for covering the nMOS transistors T₁, T₂ and the pMOS transistor T₃ is formed on the silicon substrate 1 by the plasma CVD method. As the cover film 10, a silicon oxide nitride (SiON) film, for example, is formed.

Then, a silicon oxide (SiO₂) film is grown up to about 1.0 μm by the plasma CVD method using as the TEOS gas. This silicon oxide film is used as a first interlayer insulating film 11.

Then, as the densifying process of the first interlayer insulating film 11, the first interlayer insulating film 11 is annealed at the temperature of 650° C. for 30 minute in the nitrogen atmosphere at the atmospheric pressure. Then, an upper surface of the first interlayer insulating film 11 is planarized by polishing by virtue of the CMP (Chemical Mechanical Polishing) method.

Then, as shown in FIG. 2B, a titanium (Ti) film 12 of less than 50 nm thickness, for example, about 20 nm thickness, on the first interlayer insulating film 11 by the sputtering method. In the step of forming the Ti film 12, the silicon substrate 1 is controlled at the temperature of the room temperature to 150° C.

Then, the silicon substrate 1 is loaded into the heating furnace (not shown). Then, an argon (Ar) gas and an oxygen (O₂) gas are introduced into the heating furnace at 1980 cc/min. and 20 cc/min. respectively.

Then, as shown in FIG. 2C, a titanium oxide (TiOₓ) film 12a is formed by oxidizing the overall Ti film 12 by RTA (Rapid Thermal Annealing), which is executed at the substrate temperature of 400 to 1000° C., e.g., 700° C., for an oxidation time of 10 to 120 sec, e.g., 20 sec, in the oxygen-containing atmosphere in the heating furnace. In this case, the inside of the heating furnace is set to the atmospheric pressure.

In the titanium oxide film 12a formed under such conditions, the (200) face orientation intensity becomes higher than the titanium oxide film that is formed by introducing the oxygen only into the heating furnace, an aspect ratio of the grain of the titanium oxide constituting the titanium oxide film 12a becomes small, and surface roughness becomes small. The aspect ratio is a rate of a height to a width of the grain. Details of the titanium oxide film will be described later.

In this case, the titanium oxide film 12a is an adhesion layer between a platinum film, to be described later, and the first interlayer insulating film 11 or an underlying layer of the platinum film, to be described later.

Next, steps required until a structure shown in FIG. 2D is formed will be explained hereunder.

First, a platinum (Pt) film is formed as a first conductive film 13 on the titanium oxide film 12a. The Pt film is formed by the sputtering method while setting the substrate temperature to less than 100° C. but more than 50° C., for example. In this case, a thickness of the Pt film is set to 100 to 300 nm, e.g., about 150 nm. The (222) face orientation intensity of this Pt film is increased depending on the (200) face orientation intensity of the titanium oxide film 12a, and also the surface roughness of the Pt film is decreased. Details of the Pt film will be described later.

Then, a plumbum zirconate titanate (PZT; Pb(Zr₁₋ₓTiₓ)O₃) film of 100 to 300 nm thickness is formed as a ferroelectric film 14 on the first conductive film 13 by the RF sputtering method. The compositions of Pb, Zr, and Ti constituting the PZT film are set in the range of Pb/(Zr+Ti)=1.10 to 1.15, for example.

In this case, as the method of forming the ferroelectric film 14, there are the MOD (Metal Organic Deposition) method, the MOCVD (Metal Organic CVD) method, the sol-gel method, etc. in addition to the above. Also, as the material of the ferroelectric film 14, there are other PZT material such as PLCSZT, PLZT, etc., Bi-layered structure compound such as SrBi₂Ta₂O₉(SBT, Y1), SrBi₂(Ta,Nb)₂O₉ SBTN, YZ), etc., and other metal oxide ferroelectric substance in addition to PZT.

Then, as the crystallizing process of the PZT film constituting the ferroelectric film 14, RTA (Rapid Thermal Annealing) is executed at the temperature of about 585° C. for about 90 second in the oxygen atmosphere.

Then, an iridium oxide (IrOₓ) film is formed as a second conductive film 15 on the ferroelectric film 14 by the two-step reactive sputter method. As the first step, the IrOₓ film is formed to have a thickness of 25 to 100 nm. In this case, as the gases introduced into the sputter atmosphere, the argon gas is set to 100 cc/min. and the oxygen (O₂) gas is set to 30 to 60 cc/min. Then, RTA is applied to the IrOₓ film at the temperature of about 725° C. for about 20 second in the oxygen atmosphere. Then, as the second step, the IrOₓ film is further formed to have a thickness of 100 to 225 nm. In this case, the argon gas and the oxygen gas introduced into the sputter atmosphere are set to the same flow rate.

Next, steps required until a structure shown in FIG. 2E is formed will be explained hereunder.

First, a plurality of capacitor upper electrodes 15a are formed over the element isolation insulating film 2 in the memory cell region A by patterning the second conductive film 15. Then, capacitor dielectric films 14a are formed by patterning the ferroelectric film 14.

Then, an alumina film of about 20 to 50 nm thickness is formed as a capacitor protection insulating film 16 on the capacitor upper electrodes 15a, the capacitor dielectric films 14a, and the first conductive film 13 by the sputter. In this case, as the capacitor protection insulating film 16, a PZT film, a silicon nitride film, a silicon nitride oxide film, or the like may be employed in addition to the alumina film.

Then, as shown in FIG. 2F, the capacitor protection insulating film 16, the first conductive film 13, and the titanium oxide film 12a are patterned in a stripe shape extending in the extending direction of the word line (gate electrode) beneath a plurality of capacitor upper electrodes 15a by using a resist mask (not shown). As a result, a capacitor lower electrode 13a made of the first conductive film 13 is formed. In this case, the titanium oxide film 12a may be considered as a part of the capacitor lower electrode 13a.

One capacitor Q consists of one capacitor upper electrode 15a, the capacitor dielectric films 14a formed thereunder, and the capacitor lower electrode 13a.

Then, as shown in FIG. 2G, a silicon oxide film of about 1 μm thickness is formed as a second interlayer insulating film 17 on the capacitor protection insulating film 16, the first interlayer insulating film 11, and the capacitor Q. This silicon oxide film is formed by the CVD method using TEOS. Then, an upper surface of the second interlayer insulating film 17 is planarized by the CMP method. In this example, a remaining thickness of the second interlayer insulating film 17 after the CMP is set to about 300 nm on the capacitor in the memory cell region A.

Next, steps required until a structure shown in FIG. 2H is formed will be explained hereunder.

First, the second interlayer insulating film 17, the first interlayer insulating film 11, and the cover film 10 are patterned. Thus, first and second contact holes 17a, 17b are formed on the first and second n-type impurity diffusion regions 7a, 7b respectively and simultaneously third and fourth contact hole 17c, 17d are formed on the first and second p-type impurity diffusion region 8a, 8b, respectively.

The first contact hole 17a is formed on the first n-type impurity diffusion regions 7a formed near both sides of the p-well 3a in the memory cell region A. Also, the second contact hole 17b is formed on the second n-type impurity diffusion region 7b that is put between two gate electrodes 5a, 5b in the center of the p-well 3a.

Then, a Ti film of 20 nm thickness and a TiN film of 50 nm thickness are formed sequentially in the first to fourth contact holes 17a to 17d and on the second interlayer insulating film 17 by the sputter, and then a W film is formed on the TiN film by the CVD method. The W film is formed to have a thickness that can bury perfectly insides of the first to fourth contact holes 17a to 17d.

Then, the Ti film, the TiN film, and the W film are polished by the CVD method to be removed from an upper surface of the second interlayer insulating film 17. Thus, the Ti film, the TiN film, and the W film left in the first to fourth contact holes 17a to 17d are used as first to fourth conductive plugs 18a to 18d respectively.

Then, a silicon nitride film is formed as an oxidation-preventing film 19 on the first to fourth conductive plugs 18a to 18d and the second interlayer insulating film 17.

Then, as shown in FIG. 2I, fifth and sixth contact holes 19a, 19b are formed on the capacitor upper electrode 15a and on the contact region of the capacitor lower electrode 13a respectively by patterning the oxidation-preventing film 19 and the second interlayer insulating film 17.

Then, the crystallinity of the ferroelectric film 14 constituting the capacitor dielectric film 14a is recovered by the annealing that is executed at about 500 to 600° C. for 60 minute in the oxygen atmosphere. In this case, oxidation of the tungsten constituting the first to fourth conductive plugs 18a to 18d can be prevented by the oxidation-preventing film 19. Then, the oxidation-preventing film 19 is removed by the etching-back.

Then, a metal film is formed on the second interlayer insulating film 17 and the first to fourth conductive plugs 18a to 18d. As the metal film, a titanium nitride (TiN) film of 150 nm thickness, an aluminum film of 500 nm thickness, a titanium (Ti) film of 5 nm thickness, and a TiN film of 100 nm thickness, for example, are formed in sequence on the second interlayer insulating film 17.

Then, as shown in FIG. 2J, first to fourth aluminum wirings 20a to 20d and a conductive pad 20e are formed by patterning the metal film by virtue of the photolithography method.

The first aluminum wiring 20a in the memory cell region A is extended from an upper surface of the first conductive plug 18a to an inside of the contact hole 19a to connect electrically the capacitor upper electrode 15a and the first conductive plug 18a. As a result, the capacitor upper electrode 15a is connected electrically to the first n-type impurity diffusion region 7a via the first aluminum wiring 20a and the first conductive plug 18a. Also, the second aluminum wiring 20b in the memory cell region A is connected to the capacitor lower electrode 13a via the sixth contact hole 19b.

The third and fourth aluminum wirings 20c, 20d are connected electrically to the third and fourth conductive plugs 18c, 18d via the third and fourth conductive plugs 18c, 18d in the peripheral circuit region B respectively.

The conductive pad 20e in the memory cell region A is formed like an island on the second conductive plug 18b, and is connected electrically to the bit line (not shown) formed thereover. The conductive pad 20e and the second conductive plug 18b, are formed to connect electrically the bit line and the second n-type impurity diffusion region 7b.

After the first to fourth aluminum wirings 20a to 20d and the conductive pad 20e are formed, a third interlayer insulating film is formed, then a conductive plug is formed, and the bit line, etc. are formed on the third interlayer insulating film. But their details will be omitted herein.

By the way, it has become apparent by the experiment that difference in the (200) face orientation intensity of the titanium oxide film 12a used as the underlying film of the above capacitor lower electrode 13a is caused according to the oxidation conditions of the Ti film 12.

First, a plurality of samples in which the titanium film of 20 nm thickness is formed on the insulating film made of silicon oxide, which is formed on the silicon substrate, were prepared. Then, the titanium oxide films were formed by oxidizing the titanium films in these samples in the furnace at the atmospheric pressure under various conditions.

The first oxidizing conditions were set such that the substrate temperature is 700°0 C., a flow rate of the oxygen (O₂) gas is 20 cc/min., a flow rate of the argon gas is 1980 cc/min., and an oxidizing time is 20 second. The second oxidizing conditions were set such that the substrate temperature is 700° C., a flow rate of the oxygen (O₂) gas is 1000, cc/min., a flow rate of the argon gas is 1000 cc/min., and an oxidizing time is 20 second. The third oxidizing conditions were set such that the substrate temperature is 700° C., a flow rate of the oxygen (O₂) gas is 2000 cc/min., a flow rate of the argon gas is 0 cc/min., and an oxidizing time is 20 second.

In other words, in the first to third oxidizing conditions, an oxygen flow rate ratio (oxygen concentration) in the mixed gas was changed while keeping a total flow rate of the mixed gas of the oxygen and the argon constant, and other oxidizing conditions were set equal.

In the first oxidizing conditions, the oxygen flow rate ratio in the mixed gas of the oxygen and the argon was set to 1%. In the second oxidizing conditions, the oxygen flow rate ratio in the mixed gas of the oxygen and the argon was set to 50%. In the third oxidizing conditions, the oxygen flow rate ratio in the mixed gas of the oxygen and the argon was set to 100%.

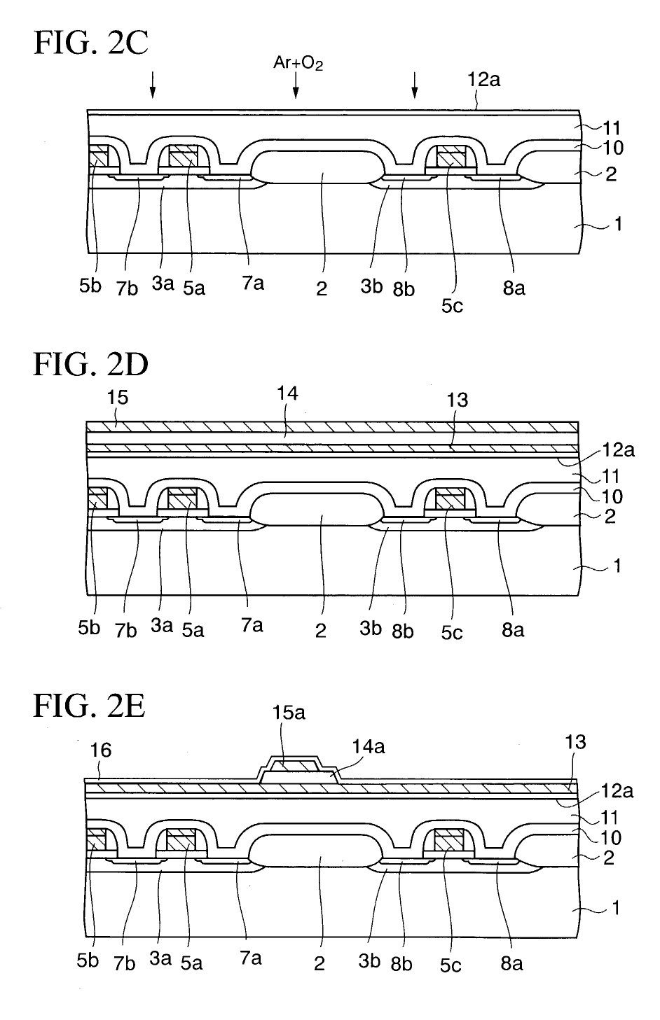

Then, when the (200) face orientation intensity of the titanium oxide (TiOₓ) films formed under the first to third oxidizing conditions was checked by the XRD (X-ray Diffractometer) method, results shown in FIG. 3 were obtained.

An abscissa of FIG. 3 denotes the oxygen concentration or the oxygen flow rate in the Ti film oxidizing step, and an ordinate denotes a half width (deg) of the (200) XRD pattern of the titanium oxide film and an integrated intensity (cps) of the (200) XRD pattern of the titanium oxide film.

According to FIG. 3, no big difference of the (200) half width was found according difference in the oxygen concentration in the oxidizing step, and it is understood that a (200) face appears on respective titanium oxide films formed under the first to third oxidizing conditions. However, it becomes apparent that, according to FIG. 3, the integrated intensity becomes different due to the difference of the oxygen concentration and thus the (200) face orientation intensity becomes different. In other words, it is understood that the (200) face orientation is increased larger as the oxygen concentration becomes lower. Also, the integrated intensity of the titanium oxide film formed by setting the oxygen flow rate ratio to 50% was two times the integrated intensity of the titanium oxide film formed by setting the oxygen flow rate ratio to 100%. As a result, the flow rate ratio of the oxygen in the oxidizing atmosphere of the titanium film is set to less than 50%, preferably less than 1%.

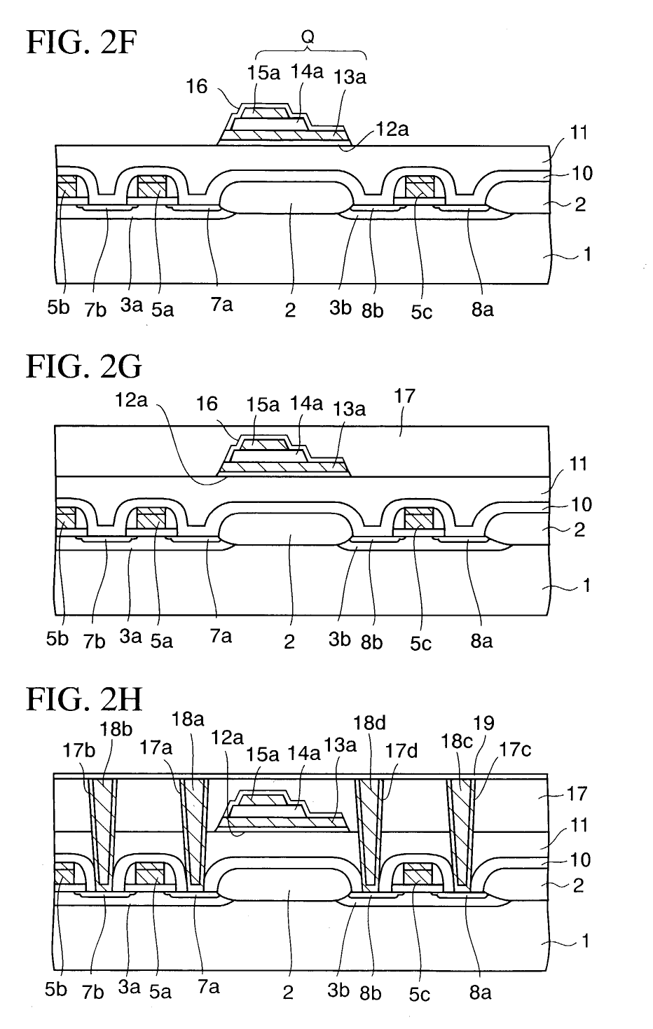

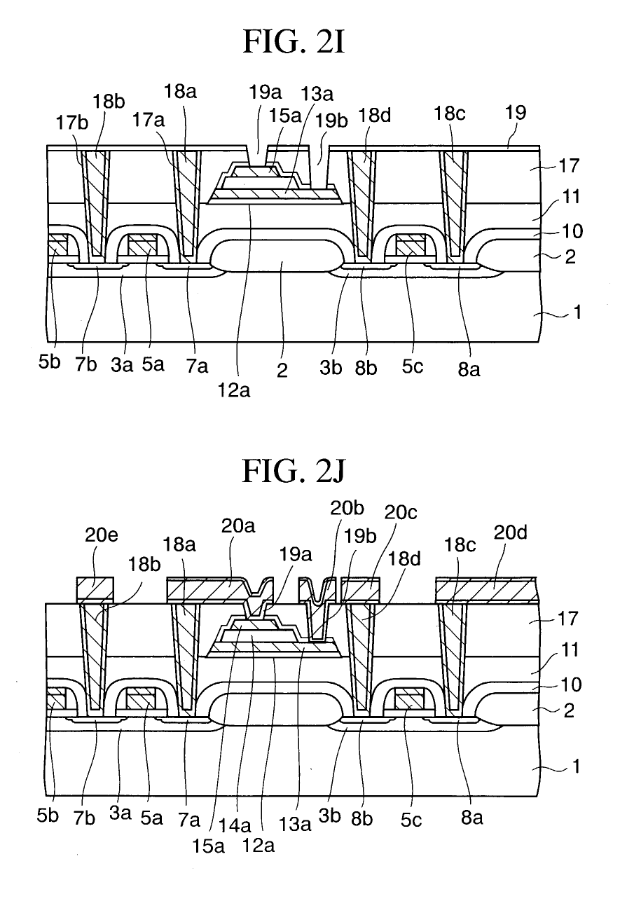

The state of grains G of the titanium oxide film formed under the oxidizing conditions in which the flow rate ratio of the oxygen is set to 1% is given as shown in FIG. 4. Also, the state of grains G of the titanium oxide film formed under the oxidizing conditions in which the flow rate ratio of the oxygen is set to 100% is given as shown in FIG. 5.

According to the comparison between FIG. 4 and FIG. 5, assume that a bottom width and a height of the grain G of the titanium oxide film are set as a₁ and b₁ respectively, a relation a₁>b₁ was satisfied in the size of the grain (particle) G of the titanium oxide formed under the oxidizing conditions in which the flow rate ratio of the oxygen is set to 1%, and also a relation a₁<b₁ was satisfied in the size of the grain G of the titanium oxide formed under the oxidizing conditions in which the flow rate ratio of the oxygen is set to 100%. More particularly, the grain G of the titanium oxide film formed under the oxidizing conditions, in which the flow rate ratio of the oxygen is set to 1%, was relatively larger in size than the grain G of the titanium oxide film formed under the oxidizing conditions, in which the flow rate ratio of the oxygen is set to 100%. Also, a surface of the titanium oxide film formed under the oxidizing conditions, in which the flow rate ratio of the oxygen is set to 100%, become rougher than a surface of the titanium oxide film formed under the oxidizing conditions, in which the flow rate ratio of the oxygen is set to 1%. The flatness of the metal film formed thereon can be improved as the surface of the titanium oxide film becomes flatter.

In this case, FIG. 4 and FIG. 5 are depicted based on the microphotographs that are picked up by SEM (Scanning Electron Microscope) respectively.

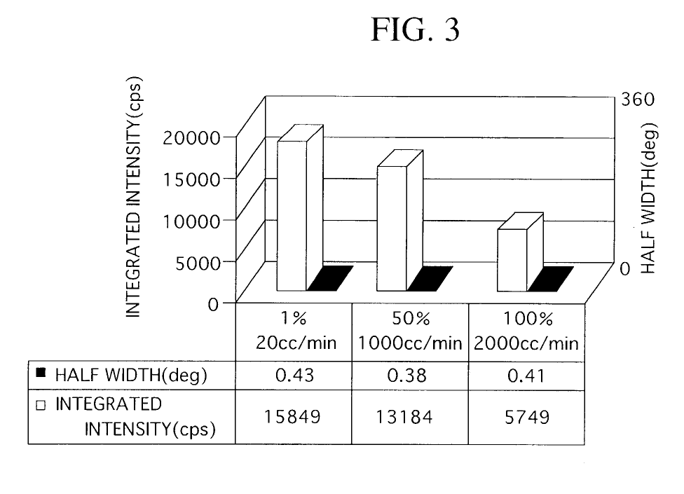

Then, the platinum film was formed on the titanium oxide film formed by oxidizing the titanium film under the oxidizing conditions, in which the flow rate ratio of the oxygen is set to 1%. Also, the platinum film was formed on the titanium oxide film formed by oxidizing the titanium film under the oxidizing conditions, in which the flow rate ratio of the oxygen is set to 100%. When (222) face orientation intensities of respective platinum films were checked by the XRD method, results shown in FIG. 6 were obtained. In other words, the integrated intensity of the (222) XRD pattern of the platinum film formed on the titanium oxide film that is formed under the oxidizing conditions, in which the flow rate ratio of oxygen is set to 1%, was 910000 cps. In contrast, the integrated intensity of the (222) XRD pattern of the platinum film formed on the titanium oxide film that is formed under the oxidizing conditions, in which the flow rate ratio of oxygen is set to 100%, was 340000 cps. In this case, the (222) face may be expressed as the (111) face.

Therefore, according to FIG. 3 and FIG. 6, it can be seen that the (222) face orientation intensity of the platinum film is increased depending upon the (200) face orientation intensity of the underlying titanium oxide film.

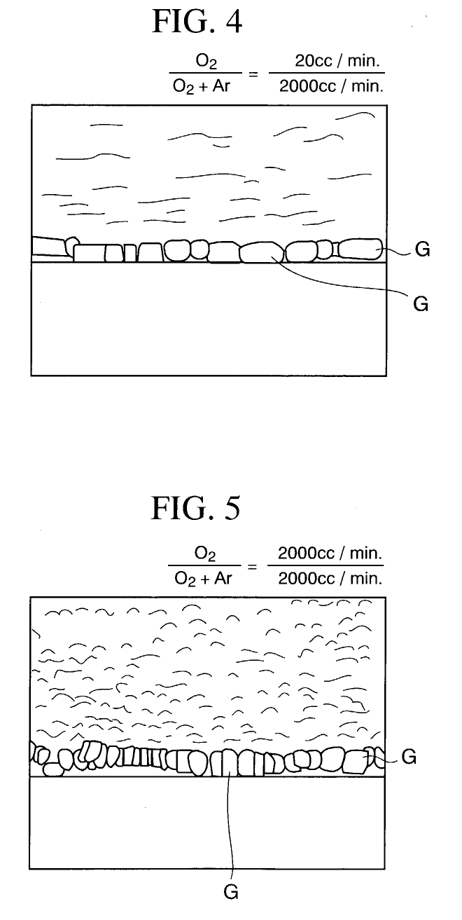

Next, when it was checked by the experiment how a fraction defective (%) of FeRAM is influenced by a growth temperature of the platinum film constituting the capacitor lower electrode, results shown in FIG. 7 were obtained.

The fraction defective indicates to what extent the defective data reading is generated in a plurality of capacitors in the FeRAM after data are written into a plurality of capacitors in the FeRAM, then the FeRAM is heated at 150° C. for 4 hours, and then the data are read from a plurality of capacitors in the FeRAM in the circumstances of 85° C., for example. In this case, the capacitor dielectric film is made of PZT, the upper electrode is made of iridium oxide, and the platinum film is formed on the titanium oxide film shown in FIG. 4.

According to this, it is found that the fraction defective in first to third FeRAMs having a plurality of capacitors whose lower electrode is made of the platinum that is formed at 100° C. was largely reduced rather than that in fourth to sixth FeRAMs having a plurality of capacitors whose lower electrode is made of the platinum that is formed at 550° C.

Therefore, it is understood that, if the platinum film acting as the capacitor lower electrode is formed at the low temperature, the FeRAMs having the small fraction defective can be manufactured in good yield. Preferably the growth temperature of the platinum film should be set to less than 100° C. and more than 50° C.

As one of factors that can reduce the fraction defective of the device by forming the platinum film at the low temperature, the reaction between the lower electrode and the aluminum wiring can be considered.

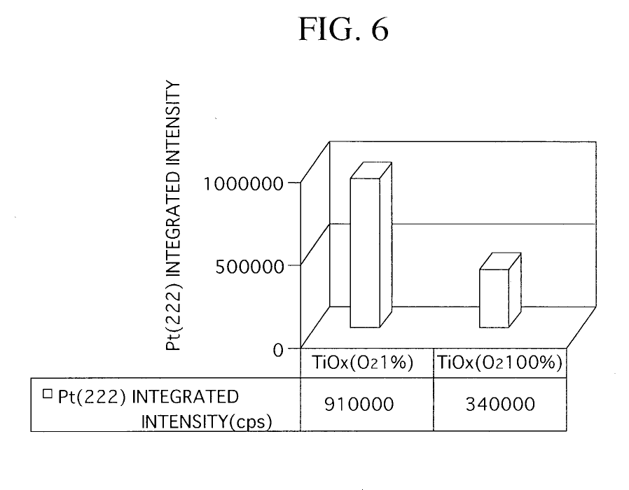

FIG. 8 is a plan view showing a monitor capacitor when viewed from the top. An upper electrode 32 is formed on a lower electrode 31, which is made of platinum formed on an interlayer insulating film 30, via a PZT film (not shown). The lower electrode 31 has a contact region that is projected from the upper electrode 32 in the lateral direction. Also, the lower electrode 31 and the upper electrode 32 are covered with an insulating film (not shown). A first aluminum wiring 33 is connected to an upper surface of the upper electrode 32 via a first contact hole 34. This first aluminum wiring 33 is connected electrically to a first monitor pad 35. Also, a second aluminum wiring 37 is connected to a contact region of the lower electrode 31 via a second contact hole 36. This second aluminum wiring 37 is connected electrically to a second monitor pad 38. The first and second aluminum wirings 33, 37 have the triple-layered structure, in which the aluminum film is put between the titanium nitride films in the vertical direction, respectively. In this case, the titanium oxide film shown in FIG. 4 is formed between the lower electrode 31 and the interlayer insulating film 30.

Assume that the capacitor having the lower electrode 31 made of platinum, which is formed at the film forming temperature (substrate temperature) of 550° C. by the sputter, is Q₁. Also, assume that the capacitor having the lower electrode 31 made of platinum, which is formed at the film forming temperature of 100° C. by the sputter, is Q₂.

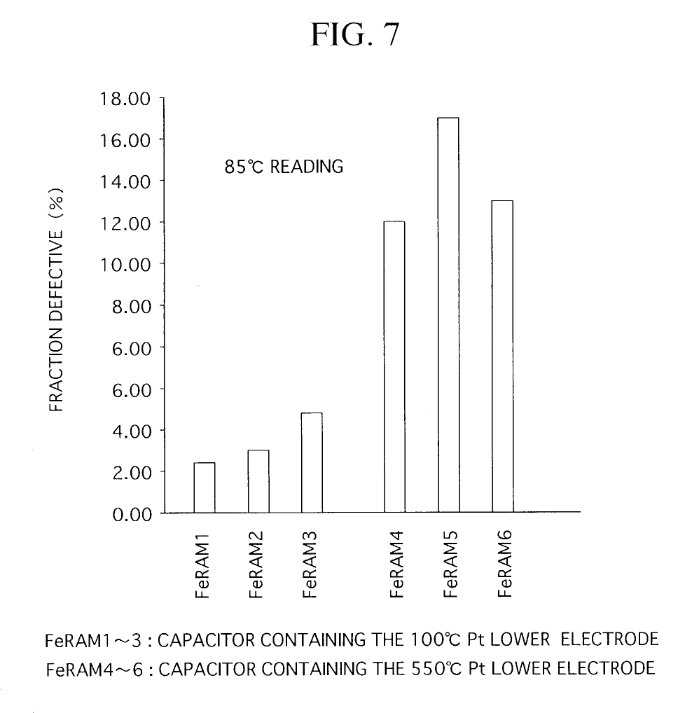

Then, when the capacitor Q₁ was heated at 370° C. for 0.5 hour and then was watched by the microscope from the top, the contact region between the lower electrode 31 and the second aluminum wiring 37 discolored, as shown in FIG. 9A. In contrast, when the capacitor Q₂ was heated at 370° C. for 0.5 hour and then was watched by the microscope from the top, change of the contact region between the lower electrode 31 and the second aluminum wiring 37 from the initial state was not found, as shown in FIG. 9B.

It may be considered that, in the capacitor Q₁ in which the lower electrode 31 was made of the platinum formed at the film forming temperature of 550° C., the aluminum film reacted with the lower electrode 31 via the titanium nitride film constituting the lower layer portion of the aluminum wiring 37, and thus the color of the contact region was changed.

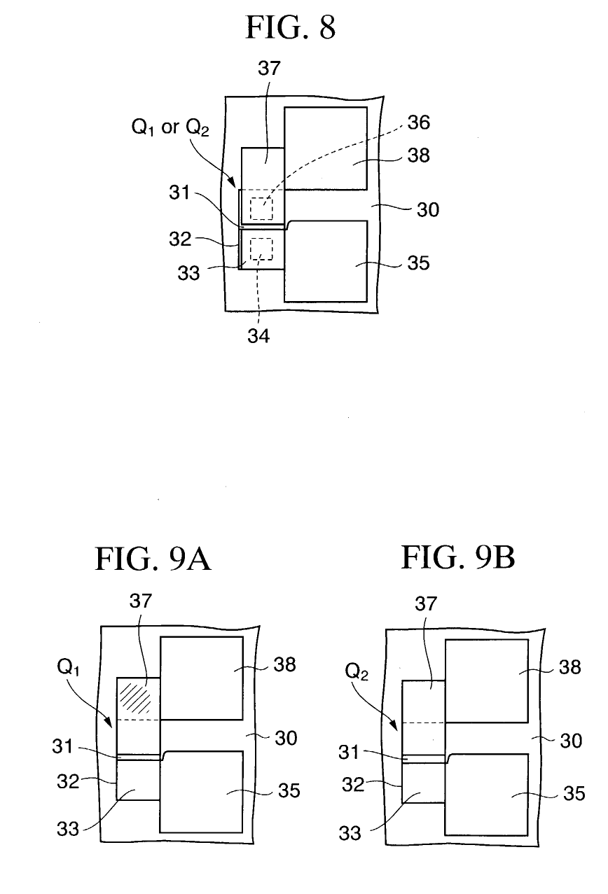

Therefore, when the capacitor having the lower electrode which is made of the platinum formed at the film forming temperature of 550° C. was heated and then a cross section of the contact portion between the lower electrode and the aluminum wiring was checked, results shown in FIG. 10 were obtained.

In FIG. 10, a lower electrode 41 of the capacitor was formed on a first insulating film 40 made of silicon oxide, then a second insulating film 42 made of silicon oxide was formed on the lower electrode 41 and the first insulating film 40, and then a contact hole 43 was formed in the second insulating film 42 on the contact region of the lower electrode 41. A titanium oxide film 44, which was formed by oxidizing the titanium film in the mixed gas atmosphere consisting of argon and oxygen, was formed between the lower electrode 41 and the first insulating film 40. Also, an aluminum wiring 46 having a structure in which an aluminum film 46a was put between titanium nitride films (conductive underlying films) 46b, 46c in the vertical direction was formed in the contact hole 43 and on the second insulating film 42. This aluminum wiring 46 was connected to the lower electrode 41 via the contact hole 43. In this case, a film thickness of the lower titanium nitride film 46b constituting the aluminum wiring 46 was set to about 150 nm at a bottom portion of the contact hole 43.

At such bottom portion of the contact hole 43, the aluminum film 46a reacted with the lower electrode 41 via the titanium nitride film 46b, and thus reaction product 47 made of aluminum and platinum was formed. If a volume of the reaction product 47 is increased, it is possible that the second insulating film 42 is lifted up around the contact region of the lower electrode 41 and thus the contact between the lower electrode 41 and the aluminum wiring 46 becomes defective.

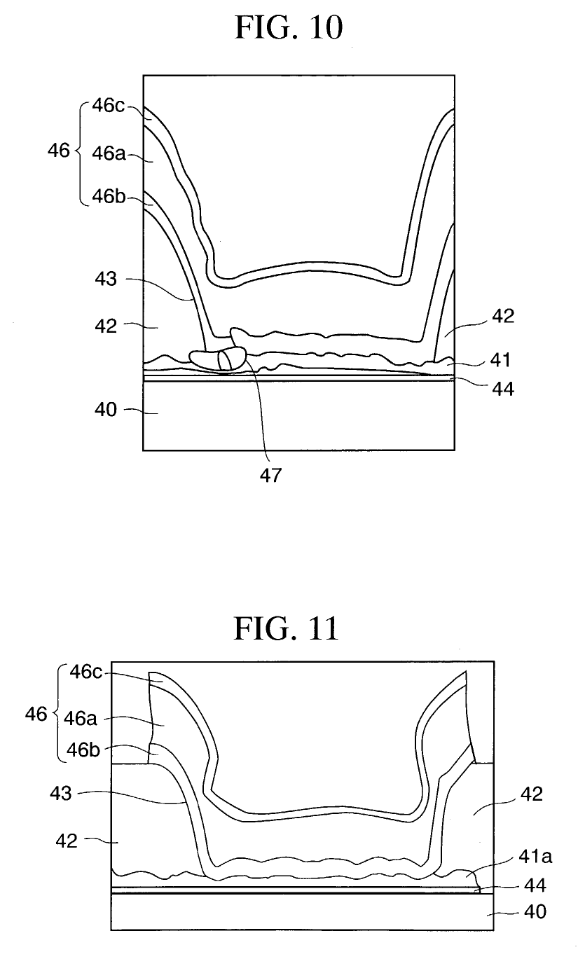

In contrast, when the capacitor having a lower electrode 41a made of the platinum that is formed at the film forming temperature (substrate temperature) of 100° C. was heated at 370° C. and then a cross section of the contact portion between the lower electrode 41a and the aluminum wiring 46 was checked, results shown in FIG. 11 were obtained. In FIG. 11, no reaction product was formed between the aluminum wiring 46 and the lower electrode 41a. In this case, in FIG. 11, the same symbols as those in FIG. 10 denote the same elements.

Meanwhile, since the platinum film was formed at the low film forming temperature, hydrogen catalytic effect of the platinum film was reduced. Therefore, in the ferroelectric capacitor having the lower electrode made of the platinum that was formed at the low film forming temperature, e.g., less than 100° C., degradation caused due to the reducing action can be suppressed, so that the fraction defective of the device can be reduced.

In this case, in the above embodiment, the capacitor lower electrode 13a is formed of the platinum, but the lower electrode may be formed of iridium. The (222) face orientation intensity of the iridium also depends on the (200) face orientation intensity of the titanium oxide 12a, like the platinum. Also, in the above embodiment, the argon was introduced into the atmosphere in which the titanium film is oxidized, but any inert gas such as nitrogen, helium, neon, or the like may be introduced.

As described above, according to the present invention, the adhesion layer made of the titanium oxide having the grain size, a width of which is larger than a height, is formed between the lower electrode, which is made of noble metal constituting the capacitor, and the insulating film. Therefore, the (200) face orientation intensity of the adhesion layer can be enhanced and the planarization can be improved. Also, the planarization of the lower electrode formed on the adhesion layer can be improved and thus the contact between the lower electrode and the wiring can be improved.

Also, as the (200) face orientation intensity of the adhesion layer is enhanced, the (222) face orientation intensity of the metal film used as the lower electrode formed thereover can be enhanced. Therefore, film quality of the ferroelectric film formed on the lower electrode can be improved.

In addition, in the case that the capacitor lower electrode is formed of the platinum film, if the platinum film is formed at the temperature of less than 100° C. by the sputter method, the contact of the aluminum film, which is formed on the capacitor lower electrode via the conductive underlying film, to the capacitor lower electrode can be improved.

What is claimed is:

1. A semiconductor device comprising:
a first insulating film formed over a semiconductor substrate;
an adhesion layer formed on the first insulating film and made of titanium oxide having grains a width of which is larger than a height;
a capacitor lower electrode formed on the adhesion layer and containing a noble metal;
a capacitor dielectric film formed on the capacitor lower electrode and made of ferroelectric material; and
a capacitor upper electrode formed on the capacitor dielectric film.

2. A semiconductor device according to claim 1, wherein a film thickness of the adhesion layer is less than 50 nm.

3. A semiconductor device according to claim 1, wherein the first insulating film is a silicon oxide film.

4. A semiconductor device according to claim 1, wherein the noble metal is one of platinum and iridium.

5. A semiconductor device according to claim 1, wherein the ferroelectric material is any one of PZT, SBT, and Bi-layered compound.

6. A semiconductor device according to claim 1, further comprising:
a second insulating film for covering the capacitor upper electrode, the capacitor dielectric film, and the capacitor lower electrode;
a contact hole formed in the second insulating film on the capacitor lower electrode; and
an aluminum-containing wiring formed on the second insulating film and connected to the capacitor lower electrode via the contact hole.

7. A semiconductor device according to claim 6, further comprising:
an impurity diffusion region formed on a surface layer of the semiconductor substrate;
a hole formed in the second insulating film below the aluminum wiring; and
a conductive plug formed in the hole to connect electrically the aluminum wiring and the impurity diffusion region.

8. A manufacturing method of a semiconductor device comprising the steps of:
forming a first insulating film over a semiconductor substrate;
forming a titanium film on the first insulating film;
forming a titanium oxide film by oxidizing the titanium film in an atmosphere into which an oxygen gas is introduced at a flow rate ratio of less than 50%;
forming a first conductive film made of a noble metal on the titanium oxide film;
forming a ferroelectric film on the first conductive film;
forming a second conductive film on the ferroelectric film;
forming an upper electrode of a capacitor by patterning the second conductive film;
forming a dielectric film of the capacitor by patterning the ferroelectric film; and
forming a lower electrode of the capacitor by patterning the first conductive film.

9. A manufacturing method of a semiconductor device according to claim 8, wherein an inert gas is introduced into the atmosphere in addition to the oxygen.

10. A manufacturing method of a semiconductor device according to claim 9, wherein the oxygen gas is introduced at a flow rate ratio of less than 1% into the atmosphere.

11. A manufacturing method of a semiconductor device according to claim 10, wherein an inert gas is introduced into the atmosphere in addition to the oxygen.

12. A manufacturing method of a semiconductor device according to claim 8, wherein formation of the noble metal constituting the first conductive film is to form a platinum film at a temperature of less than 100° C.

13. A manufacturing method of a semiconductor device according to claim 8, wherein formation of the first insulating film is the step of forming a silicon oxide film by using TEOS.

14. A manufacturing method of a semiconductor device according to claim 8, wherein the ferroelectric film is made of any one of PZT, SBT, and Bi-layered compound.

15. A manufacturing method of a semiconductor device according to claim 8, wherein the titanium oxide film is shaped into a same planar shape as the lower electrode by patterning.

16. A manufacturing method of a semiconductor device according to claim 8, further comprising the steps of:
forming a second insulating film on the first insulating film and the capacitor;
forming a hole on an area of the lower electrode, which is protruded from the upper electrode, by patterning the second insulating film; and
forming an aluminum-containing wiring, which is connected to the lower electrode via an inside of the hole, on the second insulating film.

17. A manufacturing method of a semiconductor device according to claim 16, further comprising the step of:
forming a capacitor protection film for covering the capacitor before the second insulating film is formed.
